(19) United States
(12) Patent Application Publication
(10) Pub. No.: US 2025/0072230 A1
(43) Pub. Date: Feb. 27, 2025

(54) DISPLAY PANEL AND DISPLAY DEVICE

(71) Applicant: XIAMEN TIANMA DISPLAY TECHNOLOGY CO., LTD., Xiamen (CN)

(72) Inventors: Ying LI, Xiamen (CN); Yongxiang LIN, Xiamen (CN)

(73) Assignee: XIAMEN TIANMA DISPLAY TECHNOLOGY CO., LTD., Xiamen (CN)

(21) Appl. No.: 18/942,789

(22) Filed: Nov. 11, 2024

(30) Foreign Application Priority Data
Dec. 28, 2023 (CN) 202311840216.4

(51) Int. Cl. H10K 59/126; H10K 59/131; H10K 59/65; H10K 59/80

(52) U.S. Cl. CPC H10K 59/126; H10K 59/131; H10K 59/65; H10K 59/8791

(57) ABSTRACT

A display panel includes: a substrate; a display function layer located on the substrate, where the display function layer includes multiple light-emitting elements; and a light-shielding layer arranged above an emission surface of the display function layer. The display panel includes an active area and a non-active area. The light-shielding layer in the active area is thinner than the light-shielding layer in the non-active area. The light-shielding layer is provided with multiple openings. In a thickness direction of the display panel, the openings expose the light-emitting elements. Groove structures are formed in the light-shielding layer in at least part of the non-active area.

This application claims priority to Chinese Patent Application No. 202311840216.4, titled “DISPLAY PANEL AND DISPLAY DEVICE”, filed on Dec. 28, 2023 with the

China National Intellectual Property Administration, which is hereby incorporated by reference in its entirety.

### FIELD The present disclosure relates to the field of display technology, and in particular to

a display panel and a display device.

### BACKGROUND

A display panel generally includes an active area and a non-active area. Both the active area and the non-active area are provided with a BM (Black Matrix). The BM serves as a light-shielding layer to shade metal layers and avoid reflection of ambient light.

Many films are disposed in the active area, such as TFT (Thin Film Transistor) and packaging layers, which results in the active area having a thicker film structure than the non-active area. Thereby, there is a certain gap between the active area and the non-active area in the thickness direction. The BM is located over each of the foregoing films, and the films under the BM in the active area are significantly higher than the films under the BM in the non-active area. Therefore, after the BM is formed, the thickness of the BM in the active area is smaller than the thickness of the BM in the non-active area. After solvents and additives in the BM in the active area to be volatilized are discharged, involatile solvents in the BM in the non-active area may not be completely discharged because the BM in the non-active area is thicker than in the active area. Then it is easy to generate gas in the BM in the non-active area during subsequent processes. Since a surface layer of the BM in the non-active area has been cured, bulges are apt to appear in the BM in the non-active area, which increases a defect rate of the display panel.

### SUMMARY

A display panel and a display device are provided according to embodiments of the present disclosure. The foregoing problems are addressed.

In one embodiment, a display panel is provided according to an embodiment of the present disclosure. The display panel includes: a substrate; a display function layer, arranged above the substrate, where the display function layer includes multiple light-emitting elements; and a light-shielding layer, arranged above an emission surface of the display function layer; where the display panel includes an active area and a non-active area; a thickness of the light-shielding layer of the active area is smaller than a thickness of the light-shielding layer of the non-active area; multiple openings are disposed in the light-shielding layer of the active area; in a thickness direction of the display panel, the multiple light-emitting elements are exposed from the multiple openings; multiple groove structures are disposed in the light-shielding layer of at least part of the non-active area.

In one embodiment, a display device is provided according to the present disclosure, the display device includes a display panel. The display panel includes: a substrate; a display function layer, arranged above the substrate, where the display function layer includes multiple light-emitting elements; and a light-shielding layer, arranged above an emission surface of the display function layer; where the display panel includes an active area and a non-active area; a thickness of the light-shielding layer of the active area is smaller than a thickness of the light-shielding layer of the non-active area; multiple openings are disposed in the light-shielding layer of the active area; in a thickness direction of the display panel, the multiple light-emitting elements are exposed from the multiple openings; multiple groove structures are disposed in the light-shielding layer of at least part of the non-active area.

### BRIEF DESCRIPTION OF THE DRAWINGS

Drawings, which are incorporated in and constitute a part of this specification, illustrate embodiments according to the present disclosure and serve to explain principles of the present disclosure together with the specification.

In order to illustrate the embodiments of the present disclosure clearly, the drawings used in the embodiments are introduced briefly below.

FIG. 1 is a schematic structural diagram of film structures of a display panel according to an embodiment of the present disclosure.

FIG. 2 is a schematic structural diagram of a display panel according to an embodiment of the present disclosure.

FIG. 3 is a schematic diagram of film structures of a display panel along a direction AA′ in FIG. 2 according to an embodiment of the present disclosure.

FIG. 4 is a partial enlarged view of part B in FIG. 3 according to an embodiment of the present disclosure.

FIG. 5 is a schematic structural diagram of a first non-active area according to an embodiment of the present disclosure.

FIG. 6 is a schematic structural diagram of a first non-active area according to another embodiment of the present disclosure.

FIG. 7 is a schematic structural diagram of a display panel according to another embodiment of the present disclosure.

FIG. 8 is a schematic diagram of film structures of a display panel according to another embodiment of the present disclosure.

FIG. 9 is a schematic diagram of film structures of a display panel according to another embodiment of the present disclosure.

FIG. 10 is a schematic diagram of film structures of a display panel according to another embodiment of the present disclosure.

FIG. 11 is a schematic diagram of film structures of a display panel according to another embodiment of the present disclosure.

FIG. 12 is a schematic structural diagram of a groove structure according to an embodiment of the present disclosure.

FIG. 13 is a schematic structural diagram of a groove structure according to another embodiment of the present disclosure.

FIG. 14 is a schematic structural diagram of a groove structure according to another embodiment of the present disclosure.

FIG. 15 is a schematic structural diagram of a groove structure according to another embodiment of the present disclosure.

FIG. 16 is a schematic structural diagram of a groove structure according to another embodiment of the present disclosure.

FIG. 17 is a schematic structural diagram of a groove structure according to another embodiment of the present disclosure.

FIG. 18 is a schematic structural diagram of a display device according to an embodiment of the present disclosure.

Numeral references:

| | |
|---|---|
| 10: substrate, | 20: display function layer, |
| 21: light-emitting element, | 30: light-shielding layer, |
| 31: opening, | 32: groove structure, |
| 110: active area, | 120: non-active area, |
| 121: first non-active area, | 122: second non-active area, |
| 130: optical component area, | 12: planarization layer, |
| 13: pixel definition layer, | 14: first inorganic encapsulation layer, |
| 15: organic layer, | 16: second inorganic encapsulation layer, |
| 17: touch layer, | 18: support layer, |
| 19: array layer, | 40: metal wiring structure, |
| 41: isolation column structure, | 410: isolation column, |
| 42: signal line, | 50: light-blocking layer, |
| 60: color resistor layer, | 61: color resistor structure, |
| 501: red color resistor, | 502: green color resistor, |
| 503: blue color resistor, | 100: display panel |

### DETAILED DESCRIPTION

In order to understand the embodiments of the present disclosure clearly, solutions of the present disclosure are further described below. It should be noted that, embodiments of the present disclosure and features in the embodiments may be combined with each other as long as there is no conflict.

Many specific details are set forth in the following description to fully understand the present disclosure. the present disclosure may be implemented in other ways different from those described here. Apparently, the embodiments in the description are only part and not all of the embodiments of the present disclosure.

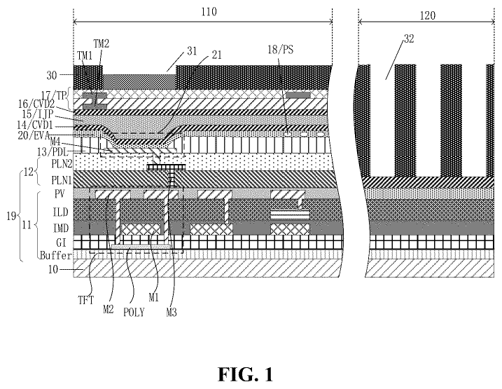

A display panel is provided according to an embodiment of the present disclosure. FIG. 1 is a schematic diagram of film structures of a display panel according to an embodiment of the present disclosure. As shown in FIG. 1, the display panel comprises: a substrate 10, a display function layer 20 and a light-shielding layer 30. The display function layer 20 is located on the substrate 10. The display function layer 20 comprises multiple light-emitting elements 21. The light-shielding layer 30 is arranged above an emission surface of the display function layer 20.

The display panel comprises an active area 110 and a non-active area 120. A thickness of the light-shielding layer 30 in the active area 110 is smaller than a thickness of the light-shielding layer 30 in the non-active area 120. Multiple openings 31 are disposed in the light-shielding layer 30 of the active area 110. In a thickness direction of the display panel, the light-emitting element 21 is exposed from the opening 31. Multiple groove structures 32 are disposed in the light-shielding layer 30 of at least part of the non-active area 120.

In an embodiment, the display panel comprises a substrate 10, which may be a glass or a flexible substrate, such as PI (Polyimide). A display function layer 20 is disposed on the substrate 10. The display function layer 20 comprises multiple light-emitting elements 21, which are configured for implementing display function of the display panel. The light-shielding layer 30 is arranged above the emission surface of the display function layer 20, which may be BM. The light-shielding layer 30 is configured to prevent light emitted from each light-emitting element 21 from crosstalk and color mixing, which affects the display effect, and shade a metal layer on the substrate 10 to avoid causing reflection of ambient light. In an embodiment, the display function layer 20 comprises a light-emitting layer, and may further comprise at least one of an electron injecting layer, an electron transporting layer, a hole blocking layer, an electron blocking layer, an air transporting layer, and a hole injecting layer, to improve transporting properties of carriers.

Referring to FIG. 1, the display panel further comprises an active area 110 and a non-active area 120. Taking FIG. 1 as an example, a pixel driving circuit and the light-emitting elements 21 are disposed at the active area 110, thus a thickness of films of the active area 110 is relatively thick. In the non-active area 120, some films in the active area 110 do not extend to the non-active area 120 correspondingly, such as a planarization layer 12 (PLN1, PLN2), a pixel definition layer 13 (PDL), an organic layer 15 (IJP), and a touch layer 17 (TP) shown in the active area 110 of FIG. 1. Therefore, the films under the light-shielding layer 30 in the active area 110 are thicker than the films under the light-shielding layer 30 in the non-active area 120. Correspondingly, after the light-shielding layer 30 is formed on the display panel by, for example, spin coating, the thickness of the light-shielding layer 30 in the active area 110 is significantly smaller than the thickness of the light-shielding layer 30 in the non-active area 120. Multiple openings 31 are disposed in the light-shielding layer 30 of the active area 110, and FIG. 1 only provides one opening 31 as an example.

The thickness of the light-shielding layer 30 in the active area 110 is different from the thickness of the light-shielding layer 30 in the non-active area 120. After solvents and additives in the light-shielding layer 30 in the active area 110 are discharged, the solvents inside the light-shielding layer 30 of the non-active area 120 may not be completely discharged because the light-shielding layer 30 in the non-active area 120 is thick. During subsequent processes, gas is easily generated in the light-shielding layer 30 in the non-active area 120, while a surface layer of the light-shielding layer 30 in the non-active area 120 has been cured, resulting in bulges easily appearing in the light-shielding layer 30 in the non-active area 120.

In an embodiment, multiple groove structures 32 are disposed in the light-shielding layer 30 of at least part of the non-active area 120. Reference is made to FIG. 1, the groove structures 32 are equivalent to increasing a volatilization path of the gas in the light-shielding layer 30 of the non-active area 120. After preparing the light-shielding layer 30, the gas generated by involatile solvents inside the light-shielding layer 30 in the non-active area 120 can be quickly discharged through the groove structures 32, to improve the volatilization speed of generated in the light-shielding layer 30 in the non-active area 120, and the volatile gas is fully volatilized. In the subsequent process, less gas is generated in the light-shielding layer 30 in the non-active area 120, to avoid that bulges appeared in the light-shielding layer 30 in the non-active area 120. In an embodiment, a light-blocking layer is provided by filling the opening 31 with a color resist. The light-blocking layer prevent external ambient light from reaching the display function layer and prevent light from being reflected when it comes into contact with the metal wiring structure. Since the gas generated by the involatile solvent inside the light-shielding layer 30 in the non-active area 120 can be quickly discharged through the groove structures 32, excessive gas generated in the light-shielding layer 30 in the non-active area 120 is decreased during subsequent processes. Correspondingly, the possibility of bulging in the light-shielding layer 30 is reduced and the yield of the display panel is improved.

The above description only explains partial structures or partial films related to the embodiments of the present disclosure. The display panel may further comprise some other film structures related to functions of the display panel. In one embodiment, in FIG. 1, in addition to the substrate 10, the display function layer 20, and the light-shielding layer 30, the display panel may further comprise an inorganic layer 11, a planarization layer 12, a pixel definition layer 13, a first inorganic encapsulation layer 14, and an organic layer 15, a second inorganic encapsulation layer 16, a touch layer 17, and a support layer 18, and may further comprise a TFT structure.

In an embodiment, specific positions of each film may be continued to refer to FIG. 1. The display panel further comprises an array layer 19 located on one side of the substrate 10. The array layer 19 comprises a pixel driving circuit formed by multiple TFTs. FIG. 1 only illustrates a transistor TFT. The pixel driving circuit is configured to drive the light-emitting element 21 to emit light. The array layer 19 comprises a buffer layer (Buffer), a first insulating layer (GI), a first active layer (POLY), a second insulating layer (IMD), a first metal layer (M1), a third insulating layer (ILD), a second metal layer (M2), a fourth insulating layer (PV), a third metal layer (M3), a fifth insulating layer (PLN1), a fourth metal layer (M4), and a sixth insulating layer (PLN2). The display panel further comprises a pixel definition layer 13 located on the side of the array layer 19 away from the substrate 10. The pixel definition layer 13 comprises multiple pixel openings located in the active area 110. The display function layer 20, the support layer 18 (PS), the first inorganic encapsulation layer 14 (CVD1), the organic layer 15 (IJP), the second inorganic encapsulation layer 16 (CVD2), the touch layer 17 (TP), and the light-shielding layer 30 are located on the side of the pixel definition layer 13 away from the array layer 19. Only the two metal layers TM1 and TM2 of the touch layer 17 are shown in FIG. 1 as an example. Specific positional relationship may be referred to FIG. 1 and may not be described here.

Therefore, the inorganic layer 11 may include a variety of insulating layers, such as Buffer, GI, IMD, ILD, PV, or the like. The planarization layer 12 may include PLN1 and PLN2, which play a role in smoothing a surface. In one embodiment, the material of the planarization layer may be transparent resin or other transparent insulating materials. The touch layer 17 comprises a metal layer and an insulating layer. The material of the first inorganic encapsulation layer 14 (CVD1) and the second inorganic encapsulation layer 16 (CVD2) may be any one of SiNₓ, SiON, SiO₂, which may be formed by chemical vapor deposition, physical vapor deposition, atomic force deposition, or the like. The planarization layer 12, the pixel definition layer 13 and the support layer 18 may include acrylic-based polymers, silicon-based polymers, and may be formed on the side of the first inorganic encapsulation layer 14 away from the substrate 10 by inkjet printing, spraying.

In some embodiments, the display panel further comprises other film structures, not all of which are shown in FIG. 1. The above-mentioned embodiments are only for illustration, and only partial structures or partial films related to the embodiments of the present disclosure are shown. Other omitted structures or films are not described in detail here, and specific films may be set according to actual conditions.

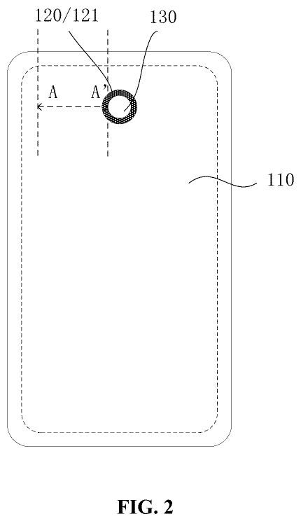

In some embodiments, FIG. 2 is a schematic structural diagram of a display panel according to an embodiment of the present disclosure. Referring to FIG. 2, the display panel comprises an active area 110 and a non-active area 120. The non-active area 120 comprises a first non-active area 121. The display panel comprises an optical component area 130. The non-active area 120 comprises a first non-active area 121 surrounding the optical component area 130. The first non-active area 121 is surrounded by the active area 110. Multiple groove structures are disposed in the light-shielding layer in the first non-active area 121.

Referring to FIG. 2, optical components are disposed at the optical component area 130 of the display panel, such as a camera. The optical component area 130 may be formed by through holes or blind holes. The first non-active area 121 may isolate the optical component area 130 and the active area 110. The first non-active area 121 surrounds the optical component area 130, and the active area 110 is arranged around the first non-active area 121. The active area 110 comprises multiple light-emitting elements. In an embodiment, metal traces and packaging structures may be disposed at the first non-active area 121 to prevent water and oxygen in the external environment from entering the display area 110 through the optical component area 130. A shielding layer is disposed in the first non-active area 121 to prevent the metal traces in the first non-active area 121 from reflecting external ambient light. Since the shielding layer is disposed in the first non-active area 121 and the first non-active area isolates the optical component area 130 and the active area 110, the shielding layer can further prevent light leakage in the active area 110 and improve the display effect.

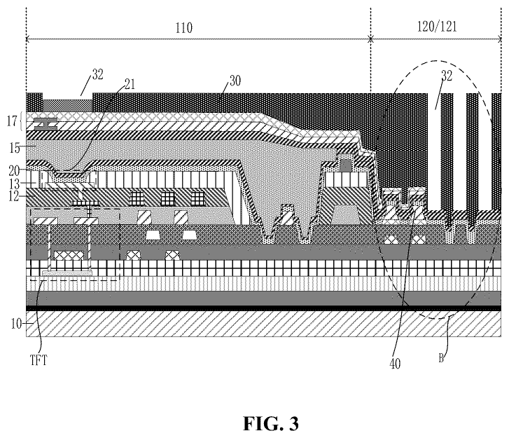

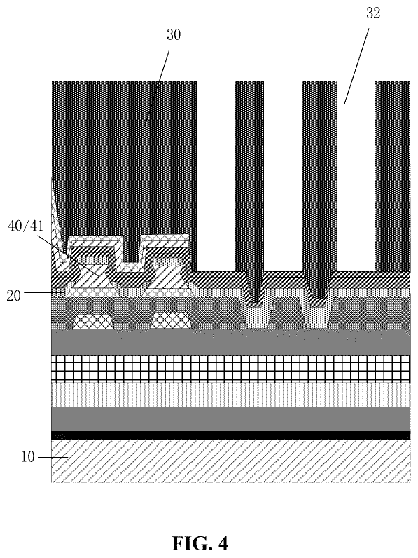

FIG. 3 is a schematic diagram of the film structure of a display panel along the direction AA′ in FIG. 2. FIG. 4 is a partial enlarged view of a part B in FIG. 3. Reference is made to FIGS. 3 and 4, the display function layer 20 is located on the substrate 10, and the light-shielding layer 30 is arranged above the emission surface of the display function layer 20. The optical components are disposed on the optical component area (referring to the positional relationship in FIG. 2). The first non-active area 121 surrounds the optical component area. Some films in the active area 110 do not extend to the first non-active area 121, such as the planarization layer 12, the pixel definition layer 13, the organic layer 15, and the touch layer 17 shown in the active area 110 in FIG. 3, which are not arranged above the first non-active area 121. Therefore, the films under the light-shielding layer 30 in the first non-active area 121 are thinner than the films under the light-shielding layer 30 in the active area 110. Therefore, the thickness of the light-shielding layer 30 formed in the first non-active area 121 is greater than the thickness of the light-shielding layer 30 formed in the active area 110 subsequently. Since the light-shielding layer in the first non-active area 121 is relatively thick, the involatile solvents inside the first non-active area 121 may not be completely discharged. In subsequent processes, gas is easily generated in the light-shielding layer in the first non-active area 121, while the surface of the light-shielding layer in the first non-active area 121 has been cured, bulges are apt to appear in a position of the light-shielding layer in the first non-active area 121. Therefore, multiple groove structures are disposed in the light-shielding layer in the first non-active area 121 to increase the volatilization path of the gas generated by the involatile solvents inside the light-shielding layer in the first non-active area 121, and the gas can be discharged quickly. Thereby, the volatilization speed of the gas generated in the light-shielding layer in the first non-active area 121 is increased, and the gas is fully volatilized.

In some embodiments, continuing to refer to FIGS. 3 and 4, a metal wiring structure 40 is disposed on the first non-active area 121, and does not overlap with the groove structures 32 in the thickness direction of the display panel.

The metal wiring structure 40 disposed on the first non-active area 121 may be a data line, a scan line, or other types of metal wiring structures. When the ambient light irradiates the metal wiring structure 40, the metal wiring structure 40 may produce light reflection, which interferes with the display of the display panel and affects the user's use. Therefore, in order to avoid the reflection of the ambient light caused by the metal wiring structure 40, the groove structures 32 and the metal wiring structure 40 do not overlap in the thickness direction of the display panel. That is, the light-shielding layer 30 is covered on the metal wiring structure 40 and blocks external light from entering.

In some embodiments, the metal wiring structure comprises an isolation column structure, the isolation column structure is arranged around the optical component area, and the display function layer is located on a side of the isolation column structure away from the substrate. The display function layer located above the isolation column structure is spaced from the display function layer on both sides of the isolation column structure.

Optical components, such as cameras, are installed in the optical component area. Water and oxygen in the outside air may enter the display panel from the optical component area. When the water and oxygen come into contact with the display function layer, the performance of pixels in the display function layer may be degraded, causing dark spots on the display panel, which affects the display effect of the display panel.

Referring to FIGS. 3 and 4, herein the isolation column structure 41 may prevent the water and oxygen from entering the display panel. The metal wiring structure 40 comprises the isolation column structure 41 arranged around the optical component area. The display function layer 20 is located on one side of the isolation column structure 41 away from the substrate 10. When the display function layer 20 is formed through evaporating, the display function layer 20 located above the isolation column structure 41 is spaced from the display function layer 20 on both sides of the isolation column structure 41 due to an existence of the isolation column structure 41.

When the water and oxygen enters through the optical component, and contacts the display function layer above the isolation column structure 41 close to the optical component area, the display function layer 20 above the isolation column structure 41 is disconnected from the display function layer 20 on both sides of the isolation column structure 41, therefore, the water and oxygen may not continue to be transferred to the display function layer 20 close to the active area, to prevent the active area from being affected by the water and oxygen.

The isolation column structure 41 is a metal structure. In order to prevent the isolation column structure 41 from reflecting the ambient light, the light-shielding layer 30 need to cover the isolation column structure 41. That is, the groove structures 32 and the isolation column structure 41 do not overlap.

In some embodiments, the non-active area may further comprise other films. FIGS. 3 and 4 are only examples. Specific unlabeled films may refer to the corresponding reference numbers in FIG. 1 and are not described again here. In some embodiments, the first non-active area may further isolate the optical component area and the active area through materials such as encapsulant.

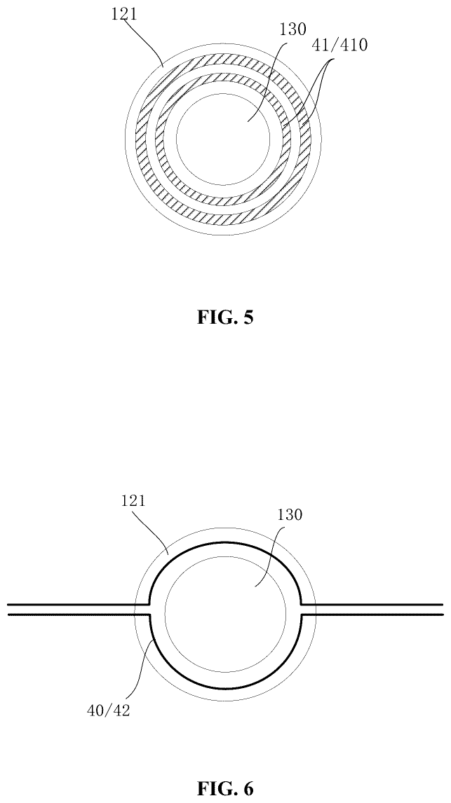

In some embodiments, FIG. 5 is a schematic structural diagram of a first non-active area according to an embodiment of the present disclosure. Reference is made to FIG. 5, the isolation column structure 41 is disposed on the first non-active area 121. The isolation column structure 41 comprises multiple isolation columns 410 that are concentric rings around the optical component area 130.

The isolation column structure 41 comprises multiple isolation columns 410, and FIG. 5 provides two isolation columns 410 exemplarily. Since the optical component area 130 is a circular structure, in order to prevent the water and oxygen in the air from entering the display panel from various angles through the optical component area 130, the isolation columns 410 are concentric rings around the optical component area 130. Multi-layer isolation columns 410 can fully isolate the contact between the water and oxygen in the outside air and the display function layer in the active area, ensuring the display effect of the display panel.

In some embodiments, the isolation column structure may comprise multiple isolation columns or may comprise one isolation column, which is not specifically limited herein. When the isolation column structure comprises one isolation column, the thickness and height of the isolation column may also be set according to actual situations to achieve an excellent effect of isolating the water and oxygen in the outside air from the display function layer in the active area. The thickness and height of the multiple isolation columns may also be set according to actual situations to achieve an excellent isolation effect, and the embodiments of the present disclosure are only exemplary.

In some embodiments, the display panel comprises multiple pixel units, the pixel units are electrically connected to the pixel driving circuit through signal wires to perform display under the control of the pixel driving circuit. Therefore, herein the signal wires need to bypass a location of the optical component area to connect to the pixel driving circuit. Therefore, the metal wiring structure comprises multiple signal wires, which are arranged in the first non-active area to bypass the optical component area.

FIG. 6 is a schematic structural diagram of a first non-active area according to another embodiment of the present disclosure. As shown in FIG. 6, the metal wiring structure 40 comprises multiple signal wires 42, such as scanning signal wires. Since optical components need to be placed on the optical component area 130, in order to prevent the signal wires from passing through the optical component area 130 and blocking the optical components, the signal wires are arranged to be wound in the first non-active area 121 to avoid the optical component area 130. In a case that the ambient light irradiates the signal wires, reflection may occur. Therefore, herein the light-shielding layer is covered on the signal wires to prevent the signal wires from reflecting the ambient light. That is, the groove structures do not overlap with the signal wires in the first non-active area 121.

FIG. 6 only illustrates that a signal line is disposed in the first non-active area. Therefore, only one signal line disposed in the first non-active area does not limit the number of signal wires.

In the above embodiments, the signal line is a scanning signal line. In some embodiments, the signal line may also be a data signal line, a power voltage signal line, or other types of signal wires, which are not limited herein. Various types of metal signal wires may be led out around the first non-active area.

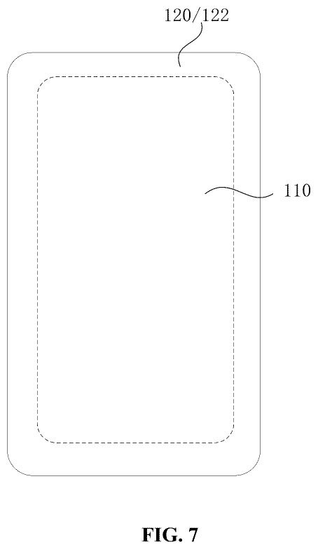

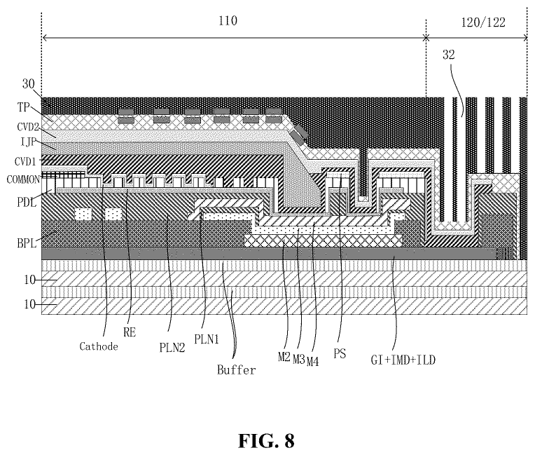

In some embodiments, a non-active area is also located around the display panel. The non-active area comprises pixel driving circuits or various peripheral circuit structures. The non-active area surrounds the active area. The thickness of the light-shielding layer in this non-active area is also larger than the thickness of the light-shielding layer of the active area. In the same way, the involatile solvents inside the light-shielding layer in this non-active area may not be completely discharged. In the subsequent process, the gas may be easily generated in the light-shielding layer in the non-active area, while the surface layer of the light-shielding layer has been cured, resulting in that raised bulges are apt to appear in the light-shielding layer in the non-active area. In some embodiments, FIG. 7 is a schematic structural diagram of a display panel according to another embodiment of the present disclosure, FIG. 8 is a schematic structural diagram of a film of a display panel according to another embodiment of the present disclosure. As shown in FIG. 7 and FIG. 8, the non-active area 120 comprises a second non-active area 122; the second non-active area 122 is arranged around the active area 110; multiple groove structures 32 are disposed in the light-shielding layer 30 in the second non-active area 122.

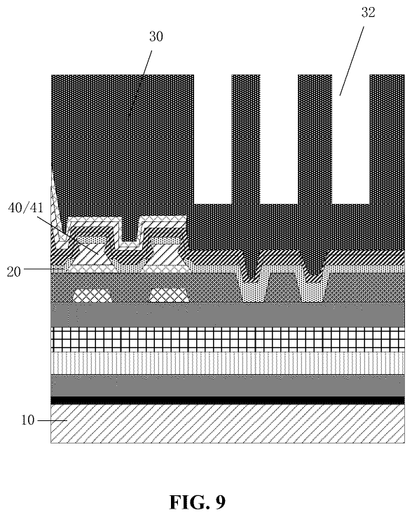

Reference is made to FIG. 8, compared with the active area 110, the second non-active area 122 does not need to be provided with light-emitting elements. Correspondingly, some films in the active area 110 do not extend to the second non-active area 122. In one embodiment, the planarization layer (PLN1, PLN2), the pixel definition layer (PDL), the organic layer (IJP), and the touch layer (TP) shown in the active area 110 of FIG. 9 are not disposed in the second non-active area 122, thereby, the films under the light-shielding layer 30 in the second non-active area 122 are relatively thin. Correspondingly, when the light-shielding layer 30 is formed on the display function layer of the display panel, the thickness of the light-shielding layer in the active area 110 is smaller than the thickness of the light-shielding layer 30 in the second non-active area 122. Therefore, multiple groove structures are disposed in the light-shielding layer of the second non-active area 122. The groove structures increase the volatilization path of the gas generated by the light-shielding layer in the second non-active area 122. After the light-shielding layer 30 is prepared, the gas generated by the involatile solvents inside the light-shielding layer 30 in the second non-active area 122 can be quickly discharged through the groove structure 32. Accordingly, the volatilization speed of the volatile gas generated in the light-shielding layer 30 in the second non-active area 122 is increased to make the volatile gas fully volatilize. In the subsequent process, less gas is generated by the light-shielding layer 30 in the second non-active area 122, which does not form raised bulges on the light-shielding layer 30 in the second non-active area 122.

In an embodiment, the second non-active area may comprise a VSR (Vertical Shift Register) circuit and other peripheral circuits. A specific circuit structure is not shown and limited herein, which is only given as an example. Furthermore, the light-emitting element may be an organic light-emitting diode (OLED), Mini LED, Micro LED or quantum dot light-emitting diode (QLED), or the like. A specific type of the light-emitting element is not limited herein. The pixel driving circuit may be a 2TIC circuit, a 7TIC circuit or a 7T2C circuit. “2TIC circuit” refers to a pixel driving circuit that comprises two thin film transistors (T) and one capacitor (C). “7TIC circuit”, “7T2C circuit” may be deduced in this way. The specific type of the pixel driving circuit is not limited herein.

In an embodiment, FIG. 8 is provided with a two-layer substrate 10, which may be a buffer layer (Buffer) formed on a flexible substrate PI, and an inorganic layer (GI+IMD+ILD, BPL), a planarization layer (PLN1, PLN2), a reflective layer (RE), a pixel definition layer (PDL), a cathode layer (cathode), a common electrode (COMMON), a first inorganic encapsulation layer (CVD1), an organic layer (IJP), a second inorganic encapsulation layer

(CVD2), a touch layer (TP), a support layer (PS), and multiple metal layers M2, M3 and M4. In some embodiments, the display panel further comprises other film structures. The above embodiments are only for illustration, and only partial structures or partial films related to the embodiments of the present disclosure are shown FIG. 8. Other omitted structures or films are not described in detail here, and specific films may be set according to actual situations.

In some embodiments, continuing to refer to FIG. 4, the groove structures 32 penetrates the light-shielding layer 30 in the thickness direction of the display panel.

When the groove structures 32 are disposed in the light-shielding layer 30 in the non-active area 120, the groove structures 32 pass through the light-shielding layer 30. In one embodiment, through holes are arranged in the light-shielding layer 30 where the groove structures 32 through drilling holes in the light-shielding layer 30. This arrangement makes the process simple and easy to implement, increases the volatilization path of the gas generated in the light-shielding layer in the second non-active area 122, and increases the volatilization speed of the gas generated in the light-shielding layer 30 in the second non-active area 122 to make the gas fully volatilized. In the subsequent process, less gas is generated in the light-shielding layer 30 in the second non-active area 122, which does not cause the light-shielding layer 30 in the second non-active area 122 to have raised bulges.

In some embodiments, the thickness of the light-shielding layer beneath the groove structures is greater than zero in the thickness direction of the display panel.

In an embodiment, FIG. 9 is a schematic diagram of the film structure of a display panel according to an embodiment of the present disclosure, as shown in FIG. 9, the thickness of the light-shielding layer 30 beneath the groove structures 32 is greater than zero. At this position, the light-shielding layer 30 is not completely penetrated, such as by means of a half-tone mask. In a case that a metal wiring structure 40 is disposed in the display function layer 20 corresponding to the bottom of the groove structures 32, the light-shielding layer 30 retained at the bottom of the groove structures 32 can play a light-shielding role to prevent external ambient light from irradiating the metal wiring structure in the display function layer 20 and causing reflection of the external ambient light. The thickness of the light-shielding layer 30 retained at the bottom is thin, which appropriately increases the volatilization path of the gas generated by the light-shielding layer in the second non-active area 122, and improves the volatilization speed of the gas generated in the light-shielding layer 30 in the second non-active area 122 to make the gas fully volatilize. In the subsequent processes, the light-shielding layer 30 in the second non-active area 122 generates less gas, which does not cause bulges on the light-shielding layer 30 in the second non-active area 122. Herein the thickness of the light-shielding layer beneath the groove structures is greater than zero, which not only increases the volatilization path of the gas generated by the light-shielding layer in the second non-active area 122, but also plays a light-shielding role to prevent external light from reflecting. In one embodiment, the process can be simplified without adding additional films, the preparation efficiency is improved.

In different embodiments, the thickness of each film of the display panel is different. Therefore, the thickness of the light-shielding layer at the bottom of the groove structures is not limited specifically herein, and can be set according to actual needs.

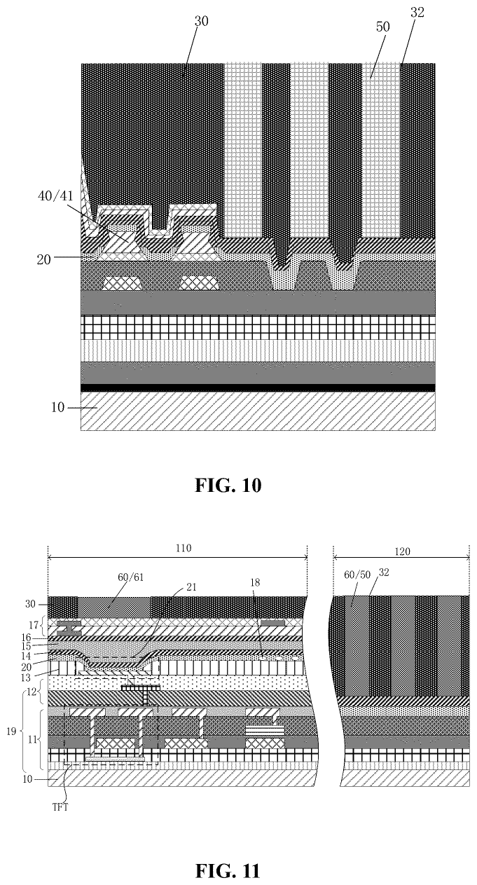

In some embodiments, a metal wiring structure may be disposed on a sidewall of the groove structure. After the groove structure is provided, the ambient light irradiating the sidewall of the groove structure may be reflected by the metal wiring structure on the sidewall, affecting the display effect of the display panel. Or in a case that a metal wiring structure is disposed in the display function layer, the external ambient light, irradiating the display function layer corresponding to the bottom of the groove structure, may be reflected, which may also affect the display effect and user experience of the display panel. Therefore, a light-blocking layer may be disposed at the bottom of the groove structure. FIG. 10 is a schematic diagram of the film structures of a display panel according to an embodiment of the present disclosure. As shown in FIG. 10, a light-blocking layer 50 is provided in the groove structure 32 of the non-active area 120.

In an embodiment, the groove structures 32 may be provided in the light-shielding layer 30 of the non-active area 120 of the display panel. In one embodiment, the groove structures 32 may be obtained by spin-coating the BM and then exposure, development and patterning, followed by a curing process. The groove structures 32 increase the volatilization path of the gas generated by the involatile solvents inside the light-shielding layer of the non-active area 120, after the light-shielding layer 30 is prepared, the gas generated by the non-volatile solvent inside the light-shielding layer 30 of the non-active area 120 may be quickly discharged through the groove structures 32. Thereby, the volatilization speed of the volatile gas generated in the light-shielding layer 30 in the non-active area 120 is increased, and the volatile gas is fully volatilized. Afterwards, the light-blocking layer 50 is disposed in the groove structures 32. In the subsequent process, a small amount of gas is generated from the light-shielding layer 30 in the non-active area 120, which will not cause bulges to appear on the light-shielding layer 30 in the non-active area 120. Herein the through holes of the groove structures maximizes the volatilization path of the gas generated by the involatile solvent inside the light-shielding layer of the non-active area 120, fully improves the volatilization speed of the gas generated in the light-shielding layer 30 in the non-active area 120, and increases the gas volatilization effect. The light-blocking layer 50 provided in subsequent process may not affect gas volatilization. The light-blocking layer 50 prevents external ambient light from reaching the display function layer 20 and prevent light from being reflected when it comes into contact with the metal wiring structure. In some embodiments, the material of the light-blocking layer 50 may be selected according to actual conditions, which is not limited herein.

In some embodiments, the display panel comprises multiple metal films, and ambient light irradiating the display panel may be reflected, affecting the user's experience.

Therefore, a polarizer is usually disposed on the display screen of the display panel to eliminate light reflection. However, setting a polarizer on the display screen requires additional manufacturing processes, and the display panel after packaging is much thick, which is not conducive to thinning and lightness. Therefore, CFOT (Color Filter On Touch) technology (depolarizing technology) is configured to replace the polarizer in the display panel to eliminate light reflection. An OLED display panel is taken as an example, a CF (Color Filter) corresponding to colors is manufactured in the light-emitting pixel region of the display panel and a black BM is manufactured in a gap between each pixel unit by using the CFOT technology, which can prevent reflected light and increase transmittance. There is no need to set up a polarizer, the process steps are reduced, thereby, the thickness of the display panel is reduced. Therefore, the CFOT technology is configured to replace the original polarizer to eliminate light reflection.

The display panel uses the CFOT technology to replace a filter and reflects external light through a color resistor layer based on the CFOT technology. FIG. 11 is a schematic diagram of the film structures of a display panel according to another embodiment of the present disclosure. As shown in FIG. 11, the display panel further comprises a color resistor layer 60. Multiple pixel apertures are disposed in the light shielding layer 30 of the active area 110. The projection of the light-emitting element 21 on the substrate is located within the projection of the pixel aperture on the substrate 10. The color resistor layer 60 comprises a color resistor structure 61 located in the pixel aperture and a light-blocking layer 50 located in the groove structure 32.

The color resistor layer 60 in the display panel replaces the polarizer of the OLED display panel in the conventional technology and is configured to eliminate reflection of external ambient light. Multiple pixel apertures are disposed in the light-shielding layer 30 of the active area 110, and the projection of the light-emitting element 21 on the substrate is located within the projection of the pixel aperture on the substrate.

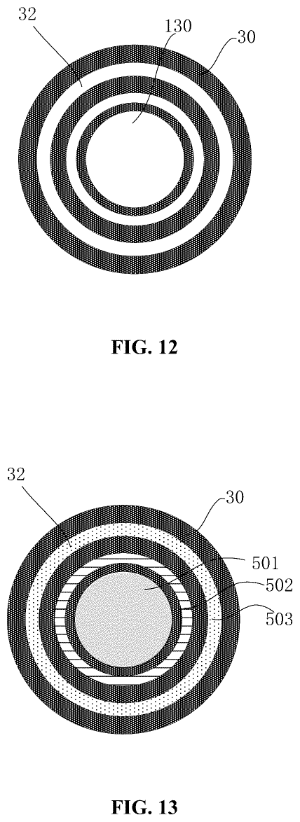

The color resistor layer 60 is disposed on both the active area 110 and the non-active area 120 to avoid reflection of the ambient light. The color resistor layer 60 of the active area 110 is a color resistor structure 61 located in the pixel aperture. Multiple color resistor structures 61 are disposed on the display panel. Only one color resistor structure 61 is provided as an example in FIG. 12. The color resistor structure 61 may be formed using a same mask as the light-emitting element 21. The color of the color resistor structure 61 is same as the color of its corresponding light-emitting element 21. Each color resistor structure 61 may correspond to one light-emitting element 21. The color resistor structure 61 can not only prevent reflected light, but also prevent the light emitted by the light-emitting element 21 from interfering with each other, and can also improve the light transmittance. Compared with providing a polarizer, the preparation process of the display panel is greatly simplified.

In some embodiments, the color resistor layer 60 of the non-active area 120 further comprises a light-blocking layer 50 in the groove structure 32. The material of the light-blocking layer 50 is the same as the material of the color resistor structure 61, thus the light-blocking layer 50 and the color resistor structure 61 may be processed in a same manufacturing process. The light-blocking layer 50 may avoid reflection of external ambient light. The color resistor structure 61 in the pixel aperture and the light-blocking layer 50 located in the groove structure 32 are formed by a same film layer, which makes the manufacturing process of the display panel simple, can replace the role of the polarizer in the active area, and plays a role in blocking light reflection in the non-active area.

In an embodiment, FIG. 11 further comprises a touch layer 17. The touch layer 17 comprises a TP buffer layer, a TP electrode layer, and a TP insulating layer. The touch layer is located on a side of the light-emitting element 21 away from the substrate 10. The light-shielding layer 30 is disposed above the touch layer 17. The reference numbers of other films in FIG. 11 may be referred to FIG. 1 and is not described again here. In some embodiments, other film layers may also be included. This is not specifically limited herein and is only taken as an example.

In some embodiments, reference is made to FIG. 11, the light-blocking layers 50 within adjacent groove structures 32 have different colors.

FIG. 11 shows three groove structures 32. The color of the light-blocking layer 50 of the groove structures 32 may be red, blue or green. Considering the display effect of the display panel, the colors of the light-blocking layers 50 in adjacent groove structures 32 may be different, such as red, blue or green in sequence as shown in FIG. 11. These three color resistors may be mixed to prevent the light-blocking layers being located at a certain position from being all color resistors of a same color. In one embodiment, in a case that they are all set to red color resistors at a position, it will cause the position to appear reddish, affecting the final display effect. Therefore, the light-blocking layers 50 in adjacent groove structures 32 may have different colors, which can not only ensure the display effect, but also prevent light reflection.

FIG. 12 is a schematic structural diagram of a groove structure according to an embodiment of the present disclosure. As shown in FIG. 12, the groove structure 32 is arranged around the optical component area 130.

In some embodiments, the first non-active area of the display panel comprises the optical component area 130. The optical components are disposed on the optical component area 130, such as a camera. Therefore, it should be avoided that the operation of the optical components in the optical component area 130 is interfered by the wiring. Therefore, signal wires that need to pass through this area may be wound, and the signal wires are around the optical component area 130 and avoid the optical component area 130. The signal wires are metal wiring structures, which may reflect the external light and then affect the display effect. Therefore, the groove structure 32 may be arranged around the optical component area 130. The groove structure 32 has a shape which is similar to the wiring shape of the signal wires, but does not overlap with the signal wires. The groove structure 32 is provided based on the wiring shape or other packaging structures, and can fully shade the signal wires or other packaging structures. The groove structure 32 is a continuous ring shape, which can effectively prevent the water and oxygen in the air from entering the active area and play an excellent isolation effect.

In some embodiments, FIG. 13 is a schematic structural diagram of a groove structure according to another embodiment of the present disclosure. As shown in FIG. 13, the light-blocking layer is provided in the groove structure 32 in the non-active area. The light-blocking layer is a color resistor layer, which is exemplarily provided with a red color resistor 501, a green color resistor 502 and a blue color resistor 503. The color resistors provided in the three ring-shape groove structures 32 have different colors, which can not only ensure the display effect, but also prevent the reflection of the ambient light. Herein the color and material of the light-shielding layer in the groove structure 32 are not limited. The foregoing is only an example, other materials may also be configured to form the light-shielding layer to avoid ambient light reflection.

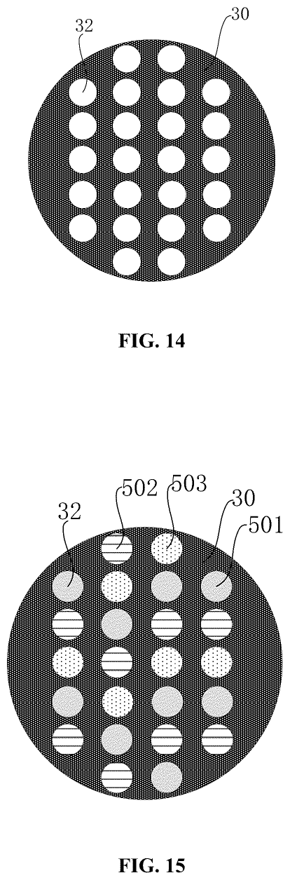

In some embodiments, FIG. 14 is a schematic structural diagram of a groove structure according to another embodiment of the present disclosure. As shown in FIG. 14, the display panel comprises a non-active area, the groove structures 32 are arranged in an array in the non-active area.

The display panel comprises a non-active area. The non-active area comprises a first non-active area and a second non-active area. The first non-active area surrounds the optical component area. The second non-active area may be located around the display panel and surrounds the active area, including multiple peripheral circuits. The thickness of the light-shielding layer in both the first non-active area and the second non-active area is greater than the thickness of the active area. Therefore, the thick light-shielding layer in the non-active area may result in failure to discharge the solvents and additives that are to be volatilized. Therefore, a groove structure 32 is provided to increase the volatilization path of the gas in the light-shielding layer. In an embodiment, the groove structures 32 are arranged in an array. The gas in the light-shielding layer of each part can be fully volatilized, and uneven volatilization can be avoided. The groove structure 32 may be circular as shown in FIG. 14, or may be in other shapes, such as rectangle, triangle, or trapezoid. Herein it is not limited but meets that the exposed area of the light shielding layer can be increased through the groove structure 32, and the evaporation rate of the solvent forming the light-shielding layer is increased.

In some embodiments, FIG. 15 is a schematic structural diagram of a groove structure according to another embodiment of the present disclosure. As shown in FIG. 15, a light-blocking layer is disposed in the groove structure 32 in the non-active area. The light-blocking layer is a color resistor layer, which is exemplarily provided with a red color resistor 501, a green color resistor 502 and a blue color resistor 503. Color resistors with different colors are filled in each groove structure 32, which can not only ensure the display effect, but also prevent the ambient light reflection. Herein the color and the material of the light-shielding layer in the groove structure 32 are not limited. The foregoing is only an example, and other materials may also be configured to form the light-shielding layer to avoid ambient light reflection.

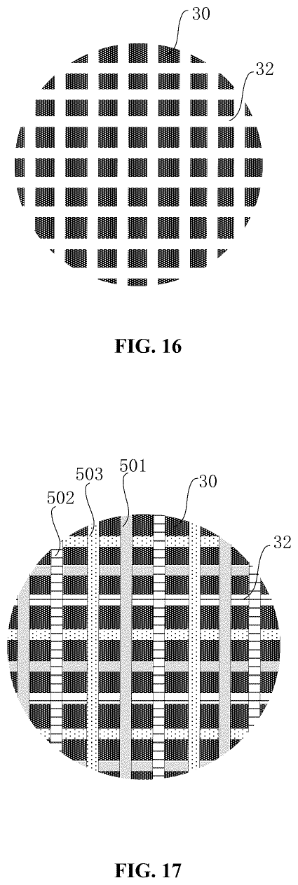

FIG. 16 is a schematic structural diagram of a groove structure according to another embodiment of the present disclosure. As shown in FIG. 16, the groove structures 32 in the non-active area are arranged in a grid.

In some embodiments, the groove structures 32 are arranged in a grid. A grid arrangement may make the position of the groove structures 32 even, which increases the volatilization path of the gas in the light-shielding layer. The gas in the light-shielding layer in each part may be fully volatilized, which can avoid uneven volatilization. The grid arrangement can avoid affecting the volatilization rate of gas in the light-shielding layer due to too many or too few groove structures in a certain area.

FIG. 17 is a schematic structural diagram of a groove structure according to another embodiment of the present disclosure. As shown in FIG. 17, a light-blocking layer is disposed in the groove structure 32 in the non-active area. The light-blocking layer is the color resistor layer, which is exemplarily provided with a red color resistor 501, a green color resistor 502 and a blue color resistor 503. The groove structure 32 arranged in a grid is filled with color resistors of different colors. The colors of the color resistors in adjacent groove structures 32 are different. The arrangement can not only ensure the display effect, but also prevent ambient light reflection. Herein the color and the material of the light-shielding layer in the groove structure 32 are not limited. The foregoing is only an example, and other materials may also be configured to form the light-shielding layer to avoid ambient light reflection.

A display device is provided according to an embodiment of the present disclosure, comprising a display panel in any one of the above embodiments. Therefore, the display device comprises features of the display panel according to embodiments of the present disclosure, and can implement beneficial effects of the display panel according to the embodiments of the present disclosure. Similarities refer to the above description of the display panel according to the embodiments of the present disclosure. It is not described again.

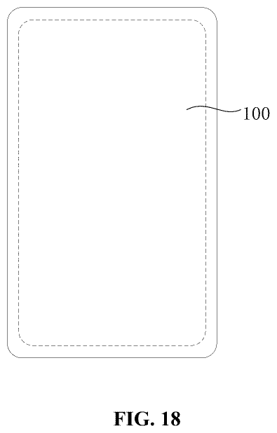

In an embodiment, FIG. 18 is a schematic structural diagram of a display device according to an embodiment of the present disclosure. As shown in FIG. 18, herein a display device comprises the display panel 100 according to any one of the above embodiments of the present disclosure. The embodiment provided in FIG. 18 only takes a mobile phone as an example to illustrate the display device. Herein the display device may be any electronic product with a display function, including but not limited to following categories, such as a mobile phone, a television, a notebook computer, a desktop monitor, a tablet computer, a digital camera, a smart bracelet, smart glasses, a vehicle monitor, medical equipment, industrial control equipment, a touch interactive terminal, or the like. The embodiment of the present disclosure is not particularly limited.

Herein the display device includes the above-mentioned display panel, thereby it can also solve same problems as the above-mentioned embodiment and achieve same effect, which will not be described again here.

It should be noted that, the relationship terms such as “first”, “second” and the like are only used herein to distinguish one entity or operation from another, rather than to necessitate or imply that an actual relationship or order exists between the entities or operations. Furthermore, the terms such as “include”, “comprise” or any other variants thereof means to be non-exclusive. Therefore, a process, a method, an article or a device including a series of elements include not only the disclosed elements but also other elements that are not clearly enumerated, or further include inherent elements of the process, the method, the article or the device. Unless expressively limited, the statement “including a . . . ” does not exclude the case that other similar elements may exist in the process, the method, the article or the device other than enumerated elements.

Various modifications made to these embodiments, and the general principle defined herein may be implemented in other embodiments without departing from the embodiments of the present disclosure. Therefore, the present disclosure is not limited to the embodiments described herein but conforms to the widest scope in accordance with principles and novel features disclosed in the present disclosure.

1. A display panel, comprising
a substrate;
a display function layer arranged above the substrate, wherein the display function layer comprises a plurality of light-emitting elements; and
a light-shielding layer, arranged above an emission surface of the display function layer;
wherein the display panel comprises an active area and a non-active area; the light-shielding layer in the active area is thinner than the light-shielding layer in the non-active area; a plurality of openings are formed on the light-shielding layer in the active area; in a thickness direction of the display panel, the plurality of openings expose the plurality of light-emitting elements; and a plurality of groove structures are formed in the light-shielding layer in at least part of the non-active area.

2. The display panel according to claim 1, wherein
the non-active area comprises a first non-active area; the display panel comprises an optical component area;
the optical component area is surrounded by the first non-active area;
the first non-active area is surrounded by the active area; and
part of the plurality of groove structures are arranged in the light-shielding layer in the first the non-active area.

3. The display panel according to claim 2, wherein
a metal wiring structure is arranged in the first non-active area; and
in the thickness direction of the display panel, the metal wiring structure does not overlap the plurality of groove structures.

4. The display panel according to claim 3, wherein
the metal wiring structure comprises an isolation column structure arranged around the optical component area, the display function layer is located on a side of the isolation column structure away from the substrate; and
the display function layer located above the isolation column structure is spaced from the display function layer located on both sides of the isolation column structure.

5. The display panel according to claim 4, wherein
the isolation column structure comprises a plurality of isolation columns; and
the plurality of isolation columns are concentric rings around the optical component area.

6. The display panel according to claim 3, wherein the metal wiring structure comprises a plurality of signal wires.

7. The display panel according to claim 1, wherein
the non-active area comprises a second non-active area;
the second non-active area is arranged around the active area; and
another part of the plurality of groove structures are arranged in the light-shielding layer in the second non-active area.

8. The display panel according to claim 1, wherein
the plurality of groove structures pass through the light shielding layer in the thickness direction of the display panel.

9. The display panel according to claim 1, wherein
in the thickness direction of the display panel, a thickness of the light-shielding layer beneath the plurality of groove structures is greater than zero.

10. The display panel according to claim 1, wherein light-blocking layers are arranged in the plurality of groove structures.

11. The display panel according to claim 10, wherein
the display panel further comprises a color resistor layer;
a plurality of pixel apertures are formed in the light-shielding layer in the active area;
a projection of a light-emitting element on the substrate is located within a projection of a corresponding pixel aperture on the substrate; and
the color resistor layer comprises a color resistor structure located in the plurality of pixel apertures and the light-blocking layers located in the plurality of groove structures.

12. The display panel according to claim 11, wherein the light-blocking layers in adjacent groove structures are in different colors.

13. The display panel according to claim 2, wherein the plurality of groove structures are arranged around the optical component area.

14. The display panel according to claim 1, wherein the plurality of groove structures are arranged in an array.

15. The display panel according to claim 1, wherein the plurality of groove structures are arranged in a grid.

16. A display device, comprising: a display panel, wherein the display panel comprises:
a substrate;
a display function layer arranged above the substrate, wherein the display function layer comprises a plurality of light-emitting elements; and
a light-shielding layer, arranged above an emission surface of the display function layer;
wherein the display panel comprises an active area and a non-active area; the light-shielding layer in the active area is thinner than the light-shielding layer in the non-active area; a plurality of openings are formed on the light-shielding layer in the active area; in a thickness direction of the display panel, the plurality of openings expose the plurality of light-emitting elements; and a plurality of groove structures are formed in the light-shielding layer in at least part of the non-active area.

17. The display device according to claim 16, wherein
the non-active area comprises a first non-active area; the display panel comprises an optical component area;
the optical component area is surrounded by the first non-active area;
the first non-active area is surrounded by the active area; and
part of the plurality of groove structures are arranged in the light-shielding layer in the first the non-active area.

18. The display device according to claim 17, wherein
a metal wiring structure is arranged in the first non-active area; and
in the thickness direction of the display panel, the metal wiring structure does not overlap the plurality of groove structures.

19. The display device according to claim 18, wherein
the metal wiring structure comprises an isolation column structure arranged around the optical component area, the display function layer is located on a side of the isolation column structure away from the substrate; and
the display function layer located above the isolation column structure is spaced from the display function layer located on both sides of the isolation column structure.

20. The display device according to claim 19, wherein
the isolation column structure comprises a plurality of isolation columns; and
the plurality of isolation columns are concentric rings around the optical component area.
